(19) United States
(12) Patent Application Publication
(10) Pub. No.: US 2015/0236071 A1
(43) Pub. Date: Aug. 20, 2015

(54) MAGNETIC MEMORY DEVICE USING IN-PLANE CURRENT AND ELECTRIC FIELD

(71) Applicant: KOREA UNIVERSITY RESEARCH AND BUSINESS FOUNDATION, Seoul (KR)

(72) Inventors: Kyung-Jin Lee, Seoul (KR); Seo-Won Lee, Seoul (KR)

(73) Assignee: KOREA UNIVERSITY RESEARCH AND BUSINESS FOUNDATION, Seoul (KR)

(21) Appl. No.: 14/428,947

(22) PCT Filed: Apr. 22, 2013
(86) PCT No.: PCT/KR2013/003367

§ 371 Date: Mar. 17, 2015

(30) Foreign Application Priority Data
Sep. 21, 2012 (KR) 10-2012-0105355

(51) Int. Cl. H01L 27/22; H01L 43/08; H01L 43/10; H01L 43/02

(52) U.S. Cl. CPC H01L 27/222; H01L 43/02; H01L 43/08; H01L 43/10

(57) ABSTRACT

Provided is a magnetic memory device for applying an in-plane current to a conductive wire adjacent to a free magnetic layer having a perpendicular magnetic anisotropy to induce a flux reversal of the free magnetic layer and simultaneously applying a voltage to each magnetic tunnel junction cell selectively to reverse magnetization of the free magnetic layer selectively at each specific voltage. The magnetic memory device may implement high density integration by reducing a volume since a spin-hall spin-torque causing a flux reversal is generated at an interface of the conductive wire and the free magnetic layer, ensure thermal stability by enhancing perpendicular magnetic anisotropy of the magnetic layer, and reduce a critical current density by increasing an amount of spin current. In addition, by increasing tunnel magnetic resistance with a thick insulating body, the magnetic memory device may increase a reading rate without badly affecting the critical current density.

### TECHNICAL FIELD

The following disclosure relates to a magnetic memory device using a magnetic tunnel junction, and more particularly, to a magnetic memory device for applying an in-plane current to a conductive wire adjacent to a free magnetic layer having a perpendicular magnetic anisotropy to induce a flux reversal of the free magnetic layer and simultaneously applying a voltage to each magnetic tunnel junction cell selectively to reverse magnetization of the free magnetic layer selectively at each specific voltage.

### BACKGROUND ART

A ferromagnetic body means a material which is spontaneously magnetized even though a strong magnetic field is not applied thereto from the outside. In a magnetic tunnel junction structure (including a first magnetic body, an insulating body and a second magnetic body) in which an insulating body is interposed between two ferromagnetic bodies, a tunnel magneto resistance effect in which an electric resistance varies depending on relative magnetization orientations of two magnetic layers occurs, since up-spin and down-spin electrons flow at different degrees at the magnetic tunnel junction structure while tunneling an insulating body. This tunnel magneto resistance has a greater value than a huge magnetic resistance generated at a spin valve structure (including a first magnetic body, a non-magnetic body and a second magnetic body) in which a non-magnetic body is interposed between two ferromagnetic bodies instead of the insulating body, and thus this is widely used as an essential technique of a magnetic memory device for sensors and information storage in order to rapidly read data recorded on a hard disk.

Due to the tunnel magneto resistance effect, relative magnetization orientations of two magnetic layers control a flow of current. Meanwhile, according to the Newton's third law, namely the law of action and reaction, if the magnetization orientation may control a flow of current, it is also possible to control a magnetization orientation of the magnetic layer by applying a current by the reaction. If a current is applied to the magnetic tunnel junction structure in a perpendicular (thickness) orientation, the current spin-polarized by the first magnetic body (the fixed magnetic layer) transfers its spinning angular momentum while passing through the second magnetic body (the free magnetic layer). A torque felt by magnetization due to the transfer of spinning angular momentum is called a spin transfer torque, and it is possible to fabricate a device for reversing magnetization of the free magnetic layer or continuously rotating the free magnetic layer by using the spin transfer torque.

An existing magnetic memory device in which a magnetic tunnel junction structure composed of a magnetic body with perpendicular magnetization is applied to a film surface basically has a structure as shown in FIG. 1, which has a structure including an electrode, a first magnetic body (a fixed magnetic layer) 101, an insulating body 102, a second magnetic body (a free magnetic layer) 103 whose magnetization orientation varies due to a current, and an electrode. Here, the second magnetic body is connected to the electrode so that a flux reversal is induced by a current perpendicularly applied to the film surface. At this time, two electric signals with high and low resistances are implemented according to relative magnetization orientations of the fixed magnetic layer and the free magnetic layer, and a magnetic memory device may be applied to record the above data as “0” or “1”.

If an external magnetic field is used instead of current in order to control magnetization of the free magnetic layer, a half-selected cell problem becomes serious as the device has a smaller size, and thus there is a limit in high density integration of the device. Meanwhile, if a spin transfer torque generated by applying a current is used to the device, flux reversal of the cell may be easily induced regardless of the size of the device. According to the physical instrument of the above spin transfer torque, the intensity of spin transfer torque generated at the free magnetic layer is determined by an amount of applied current density, and thus there exists a critical current density for flux reversal of the free magnetic layer. If both the fixed magnetic layer and the free magnetic layer are composed of material with a perpendicular magnetic anisotropy, the critical current density J_{C} may be expressed like Equation 1 below.

$${J}_{c} = \frac{2 e}{ℏ} \frac{α {M}_{S} d}{η} ( {H}_{K ⊥} - {N}_{d} {M}_{S} ) = \frac{2 e}{ℏ} \frac{α {M}_{S} d}{η} ( {H}_{K , eff} ) \qquad Equation 1$$

In Equation 1, α represents a Gilbert damping constant, h (=1.05×10⁻³⁴ J·s) is obtained by dividing a Planck constant by 2π, e (=1.6×10⁻¹⁹ C) represents an electron charge amount, η represents a spin polarization efficiency constant determined by the material and entire structure and having a value between 0 and 1, M_{S} represents a saturation magnetization amount of a magnetic body, d represents a thickness of the free magnetic layer, H_{K}⊥ (=2K_{⊥}/M_{S}) represents a perpendicular magnetic anisotropy magnetic field of the free magnetic layer, K⊥ represents a perpendicular magnetic anisotropy energy density of the free magnetic layer, a perpendicular effective anisotropic magnetic field H_{K,eff} of the free magnetic layer is defined as H_{K,eff} (=H_{K}⊥−L-N_{d}M_{S}), and N_{d} represents an effective demagnetizing field constant and has a value between 0 and 4π depending on the shape of the free magnetic layer when being described in a CGS unit.

If the cell size is reduced to make a highly integrated memory device, a super-paramagnetic limit occurs in which a recorded magnetization orientation is arbitrarily changed due to thermal energy at normal temperature. This may result in undesired deletion of recorded magnetic data. The time T during which a magnetization orientation is averagely maintained against thermal energy may be expressed as Equation 2 below.

$$τ = {τ}_{0} exp ( \frac{{K}_{eff} V}{{k}_{B} T} ) = {τ}_{0} exp ( \frac{{H}_{K , eff} {M}_{S} V}{2 {k}_{B} T} ) \qquad Equation 2$$

In Equation 2, t is a reciprocal of attempt frequency and has a value of about 1 ns, K_{eff} represents an effective anisotropic energy density (=H_{K,eff}M_{S}/2) of the free magnetic layer, V represents a volume of the device, k_{B} represents a Boltzmann constant (=1.381×10⁻¹⁶ erg/K), and T represents a Kelvin temperature.

Here, K_{eff}V/k_{B}T is defined as thermal stability Δ of the magnetic memory device. For commercialization as a non-volatile memory, a condition of Δ>50 should be satisfied in general cases. If the volume V of the free magnetic layer is reduced for high density integration of the device, K_{eff} should be increased to satisfy the condition of Δ>50, and as a result it can be found that J_{C} also increases.

Since both Δ and J_{C} are proportional to K_{off} in case of inducing a flux reversal using a spin transfer torque in the basic structure depicted in FIG. 1, it is very difficult to satisfy sufficiently high Δ and sufficiently low J_{C} simultaneously in a commercializing level.

Moreover, an amount of current provided from a device which applies a current to the magnetic tunnel junction is generally proportional to the size of the device which applies a current, and this means that the device size should be greater than a suitable level in order to apply a current density of J_{C} or above. Therefore, a size of the current supply element for applying a current of J_{C} or above may be a limit of the high density integration of the magnetic memory device.

In addition, in the basic structure, if the thickness of the insulating body increases while a current flows through the magnetic tunnel junction, the difference between up-spin and down-spin tunneling electrons becomes greater, and thus the tunnel magneto resistance increases. However, in this case, when the same voltage is applied, the amount of the tunneling current decreases, and thus it becomes very difficult to effectively apply a spin transfer torque for flux reversal to the free magnetic layer. In other words, if the thickness of the insulating body increases, the tunnel magneto resistance also increases which is an essential element in commercialization since a magnetization state may be rapidly read, but it is very difficult to implement a device which satisfies two factors simultaneously since the current density is reduced.

### DISCLOSURE

### Technical Problem

An embodiment of the present disclosure is directed to providing a magnetic memory device, which may induce a flux reversal of a free magnetic layer by means of a spin-hall spin-torque caused by an in-plane current flowing through a conductive wire adjacent to the free magnetic layer and selectively induce a flux reversal of each cell by using a voltage selectively applied to each magnetic tunnel junction cell, thereby implementing high density integration of the device as well as solving two problems of an existing magnetic tunnel junction structure in which a flux reversal of a free magnetic layer is induced by a spin transfer torque caused by a current flowing perpendicularly, namely (i) a problem in which it is difficult to simultaneously satisfy sufficiently low critical current density and sufficiently high thermal stability required for commercialization since the critical current density and the thermal stability are proportion to the same material variable, K_{eff} (effective anisotropic energy density of the free magnetic layer), and (ii) a problem in that if the insulating body of the magnetic tunnel junction structure has a greater thickness, the tunnel magneto resistance increases which allows a magnetization state to be read more rapidly, but simultaneously the current density is reduced which makes it difficult to change the magnetization state.

### Technical Solution

In one general aspect of the present disclosure, there is provided a magnetic memory device, including a plurality of magnetic memory cells, each including a fixed magnetic layer, an insulating layer and a free magnetic layer;

wherein the magnetic memory device comprises: a conductive wire provided adjacent to the free magnetic layer to apply an in-plane current to the magnetic memory cell; a magnetic field provided to the magnetic memory cells; and an element configured to independently supplying a voltage to each of the magnetic memory cells,

wherein the fixed magnetic layer is a film having a fixed magnetization orientation and made of material magnetized in a direction perpendicular to a film surface, and the free magnetic layer is a film having a variable magnetization orientation and made of material magnetized in a direction perpendicular to a film surface, and

wherein a magnetization orientation of each magnetic memory cell is selectively varied according to the applied in-plane current, the magnetic field provided to the magnetic memory cells, and the voltage supplied to each of the magnetic memory cells.

According to an embodiment of the present disclosure, the fixed magnetic layer may be made of material selected from the group consisting of Fe, Co, Ni, B, Si, Zr, Pt, Tb, Pd, Cu, W, Ta and mixtures thereof.

According to an embodiment of the present disclosure, the fixed magnetic layer may have a multi-layered film structure of a multi-layered film ((X/Y)ₙ, n≧1) formed by laminating an n number of double layers, each having an X-layer and a Y-layer, and the X-layer and the Y-layer may be independently made of material selected from the group consisting of Fe, Co, Ni. B, Si, Zr, Pt, Tb, Pd, Cu, W, Ta and mixtures thereof.

According to an embodiment of the present disclosure, the fixed magnetic layer may have a diamagnetic body structure including a first magnetic layer, a non-magnetic layer and a second magnetic layer, the first magnetic layer and the second magnetic layer may be independently made of material selected from the group consisting of Fe, Co, Ni, B, Si, Zr, Pt, Tb, Pd, Cu, W, Ta and mixtures thereof, and the non-magnetic layer may be made of material selected from the group consisting of Ru, Cu and mixtures thereof.

According to an embodiment of the present disclosure, at least one of the first magnetic layer and the second magnetic layer may have a multi-layered film structure of a multi-layered film ((X/Y)ₙ, n≧1) formed by laminating an n number of double layers, each having an X-layer and a Y-layer, and the X-layer and the Y-layer may be independently made of material selected from the group consisting of Fe, Co, Ni, B, Si, Zr, Pt, Tb, Pd, Cu, W, Ta and mixtures thereof.

According to an embodiment of the present disclosure, the fixed magnetic layer may have an exchange-biased diamagnetic body structure including an anti-ferromagnetic layer; a first magnetic layer; a non-magnetic layer; and a second magnetic layer, the anti-ferromagnetic layer may be made of material selected from the group consisting of Ir, Pt, Mn and mixtures thereof, the first magnetic layer and the second magnetic layer may be independently made of material selected from the group consisting of Fe, Co, Ni, B, Si, Zr, Pt, Tb, Pd, Cu, W, Ta and mixtures thereof, and the non-magnetic layer may be made of material selected from the group consisting of Ru, Cu and mixtures thereof.

According to an embodiment of the present disclosure, at least one of the first magnetic layer and the second magnetic layer may have a multi-layered film structure of a multi-layered film ((X/Y)ₙ, n≧1) formed by laminating an n number of double layers, each having an X-layer and a Y-layer, and the X-layer and the Y-layer may be independently made of material selected from the group consisting of Fe, Co, Ni, B, Si, Zr, Pt, Tb, Pd, Cu, W, Ta and mixtures thereof.

According to an embodiment of the present disclosure, the free magnetic layer may be made of material selected from the group consisting of Fe, Co, Ni, B, Si, Zr, Pt, Tb, Pd, Cu, W, Ta and mixtures thereof.

According to an embodiment of the present disclosure, the free magnetic layer may have a multi-layered film structure of a multi-layered film ((X/Y)ₙ, n≧1) formed by laminating an n number of double layers, each having an X-layer and a Y-layer, and the X-layer and the Y-layer may be independently made of material selected from the group consisting of Fe, Co, Ni, B, Si, Zr, Pt, Tb, Pd, Cu, W, Ta and mixtures thereof.

According to an embodiment of the present disclosure, the insulating layer may be made of material selected from the group consisting of AlOₓ, MgO, TaOₓ, ZrOₓ and mixtures thereof.

According to an embodiment of the present disclosure, the conductive wire configured to applying the in-plane current may be made of material selected from the group consisting of Cu, Ta, Pt, W, Gd, Bi, Ir and mixtures thereof.

According to an embodiment of the present disclosure, the magnetic memory device may further include a conductive wire adjacent to an outer side of the magnetic memory cell, and an Oersted magnetic field formed when a current is applied to the conductive wire may be used as a magnetic field provided to the magnetic memory cell.

According to an embodiment of the present disclosure, the magnetic memory cell may further include a magnetic layer having horizontal magnetic anisotropy at an outside of a laminated structure of the fixed magnetic layer, the insulating layer and the free magnetic layer, and a leaked magnetic field generated from the magnetic layer having horizontal magnetic anisotropy may be used as a magnetic field provided to the magnetic memory cell.

According to an embodiment of the present disclosure, the magnetic layer having horizontal magnetic anisotropy may be made of material selected from the group consisting of Fe, Co, Ni, B, Si, Zr and mixtures thereof.

The magnetic memory device may further include an anti-ferromagnetic layer adjacent to the magnetic layer having horizontal magnetic anisotropy, and the magnetic layer having horizontal magnetic anisotropy may have fixed magnetization due to the anti-ferromagnetic layer.

According to an embodiment of the present disclosure, the anti-ferromagnetic layer adjacent to the magnetic layer having horizontal magnetic anisotropy may be made of material selected from the group consisting of IrMn, FeMn, PtMn and mixtures thereof.

### Advantageous Effects

The magnetic memory device according to the present disclosure may reverse magnetization of a free magnetic layer by using an external magnetic field and a spin-hall spin-torque generated at the free magnetic layer when a current flows along a conductive wire adjacent to the free magnetic layer and also selectively induce a flux reversal to a specific cell by changing magnetic anisotropy of a magnetic layer included in each cell by means of a voltage applied to each magnetic memory cell. In a flux reversal by a spin-hall spin-torque, the critical current density is proportional to perpendicular magnetic anisotropy and volume of the magnetic layer, similar to an existing configuration, but is also proportional to an amount of spin current with respect to the applied current generated by the spin-hall effect.

Therefore, when reducing a volume of the device for high density integration of the device, perpendicular magnetic anisotropy may be increased to ensure thermal stability, and an amount of generated spin current may be effectively increased to reduce a critical current density. In other words, the memory device of the present disclosure may ensure thermal stability and satisfy a critical current density simultaneously.

In addition, since a current for generating a spin-hall spin-torque to reverse magnetization does not flow perpendicularly through the device but flows into the plane of the conductive wire, an element for supplying the current may be disposed out of an arrangement of magnetic memory cells having a magnetic tunnel junction structure, and thus the size of the element for supplying a current may be relatively freely adjusted regardless of a size of the magnetic tunnel junction structure. Therefore, a great current over a critical current density which allows a flux reversal by generating a spin-hall spin-torque may be easily applied.

Moreover, even though electrons transfer a spin-torque by tunneling an insulating body in a magnetic tunnel junction structure of an existing configuration, in the subject disclosure, the spin-hall spin-torque is generated at an interface of the free magnetic layer adjacent to the conductive wire, and thus a current does not need to flow through the insulating body in the magnetic tunnel junction structure by tunneling. Therefore, even though the thickness of the insulating body is increased to sufficiently raise tunnel magneto resistance, the critical current density may not be affected. In other words, the memory device of the present disclosure may enhance a reading rate of a magnetization state by raising tunnel magneto resistance regardless of the critical current density.

### DESCRIPTION OF DRAWINGS

FIG. 1 is a cross-sectional view showing a configuration of an existing magnetic memory device using a spin transfer torque.

FIG. 2 is a cross-sectional view showing a configuration of a magnetic memory device according to the present disclosure in which a magnetic memory cell having a magnetic tunnel junction structure is joined to a conductive wire.

FIG. 3 is a cross-sectional view showing a configuration of a magnetic memory device according to an embodiment of the present disclosure in which a plurality of magnetic memory cells having a magnetic tunnel junction structure are joined to a conductive wire.

FIG. 4a is a graph showing a presence or absence of a flux reversal of a free magnetic layer according to a current and a magnetic field applied to a cell to which an electric field is not applied, namely a cell not selected, according to an embodiment of the present disclosure.

FIG. 4b is a graph showing a presence or absence of a flux reversal of a free magnetic layer according to a current and a magnetic field applied to a selected cell to which an electric field is applied to reduce a perpendicular magnetic anisotropy of the free magnetic layer by 30% (namely, ΔK⊥(V)=0.3K⊥) according to an embodiment of the present disclosure.

FIG. 4c is a graph showing a flux reversal available area with respect to a current and magnetic field which varies depending on whether the cell is selected or not due to the presence or absence of an electric field, according to an embodiment of the present disclosure.

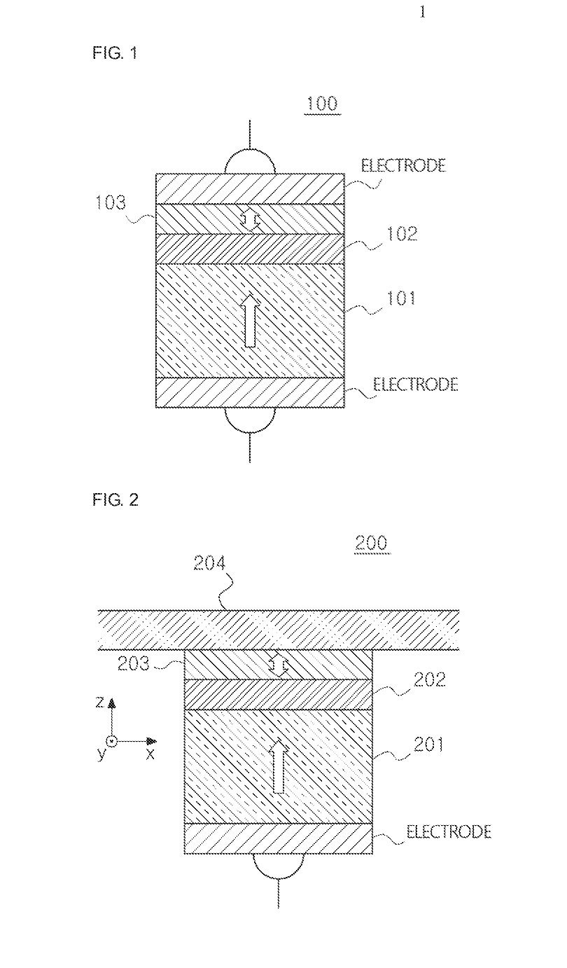

### BEST MODEL

Hereinafter, the present disclosure will be described in more detail.

A magnetic memory device according to the present disclosure does not induce a flux reversal of a free magnetic layer by using a spin transfer torque caused by a current flowing in a direction perpendicular to an existing magnetic tunnel junction structure, but induces a flux reversal of the free magnetic layer by using a spin-hall spin-torque caused by an in-plane current flowing through a conductive wire adjacent to the free magnetic layer. In addition, the magnetic memory device according to the present disclosure selectively induces a flux reversal to each cell by means of a voltage applied to each of a plurality of magnetic memory cells having a magnetic tunnel junction structure.

By doing so, problems of an existing structure in which low critical current density and high thermal stability are not satisfied simultaneously can be solved. In addition, in an existing structure, if an insulating body of the magnetic tunnel junction structure has a greater thickness, tunnel magneto resistance increases which allows a magnetization state to be read more rapidly, but simultaneously a current density decreases which makes it difficult to change the magnetization state. However, this problem may also be solved in the present disclosure. In addition, a device may have high density integration. In other words, in the magnetic memory device of the present disclosure, a device size is reduced to implement high density integration and maintain thermal stability, and a reading rate of a memory is enhanced by increasing tunnel magneto resistance while lowering a critical current density.

The magnetic memory device of the present disclosure induces a flux reversal of the free magnetic layer by using a spin-hall spin-torque generated by a current flowing in a conductive wire adjacent to the free magnetic layer and an external magnetic field, and the critical current density for a flux reversal is structurally independent from the thickness of the insulating body which determines thermal stability and tunnel magneto resistance. In addition, in order to select a cell, a voltage is applied to a selected cell to form a magnetic field, and the change of magnetic anisotropy caused therefrom is used.

The magnetic memory device according to the present disclosure includes a fixed magnetic layer, an insulating layer, a free magnetic layer and a conductive wire. The fixed magnetic layer is a film having a fixed magnetization orientation and made of material magnetized in a direction perpendicular to a film surface, and the free magnetic layer is a film having a variable magnetization orientation selected changed by a current applied through an adjacent conductive wire as well as an external magnetic field and an external electric field and made of material magnetized in a direction perpendicular to a film surface.

When an in-plane current flows through a conductive wire adjacent to the free magnetic layer, a spin-hall spin-torque is generated at the free magnetic layer by the spin-hall effect, and when an external magnetic field is applied, the magnetization of the free magnetic layer is reversed. At this time, in order to selectively induce a flux reversal to a cell, a voltage is applied to a cell which is to be selected. The cell to which the voltage is applied forms an electric field due to the applied voltage, and thus a magnetic anisotropy of the magnetic layer varies. Therefore, a flux reversal may be induced only to a selected cell by applying a voltage thereto.

The current applied to the conductive wire is provided from an element which is connected to the conductive wire to apply a current, and the voltage applied to each cell is provided from an element which is connected to each cell to apply a voltage. The element for proving a current or a voltage may be a transistor or a diode.

In order to apply an external magnetic field, there may be used a method of disposing a ferromagnetic body in or out of an arrangement of magnetic tunnel junction cells to use a leaked magnetic field generated therefrom, a method of disposing an additional conductive wire adjacent to the element to use an Oersted magnetic field formed when a current flows in the conductive wire, and a method of providing a magnetic layer with horizontal magnetic anisotropy at an outer side of a laminated structure of a fixed magnetic layer, an insulating layer and a free magnetic layer to use a leaked magnetic field generated therefrom.

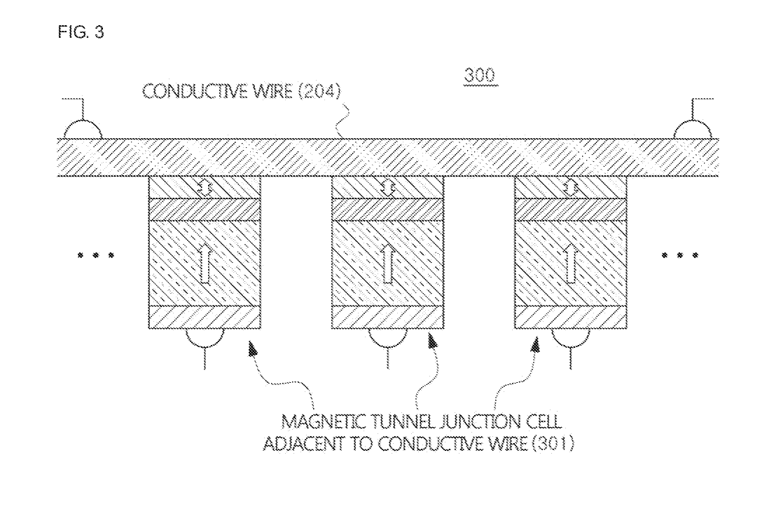

FIG. 2 is a cross-sectional view showing a configuration of a magnetic memory device according to the present disclosure in which a magnetic memory cell having a magnetic tunnel junction structure is joined to a conductive wire.

The device according to the present disclosure basically includes an electrode, a fixed magnetic layer 201 with perpendicular magnetization, an insulating layer 202, a free magnetic layer 203 with perpendicular magnetic anisotropy, and a conductive wire 204, wherein a magnetization orientation of the free magnetic layer 203 selectively varies according to an in-plane current flowing in the conductive wire 204 as well as an external magnetic field and an external electric field.

If a voltage is applied to a cell to be selected in order to selectively induce a flux reversal to a magnetic tunnel junction cell, magnetic anisotropy of the free magnetic layer of the cell varies. In this state, if a suitable in-plane current is applied through the conductive wire 204 and an external magnetic field is also applied, the free magnetic layer receives a spin-hall spin-torque and induces a flux reversal.

Referring to FIG. 2, the device includes an electrode, a fixed magnetic layer 201, an insulating layer 202, a free magnetic layer 203 and a conductive wire 204, and current flows to the conductive wire 204 in a horizontal direction for a flux reversal of the free magnetic layer.

Up-spin and down-spin electrons flowing in the conductive wire are biased into different directions due to spin-trajectory interaction, thereby causing a spin-hall effect, and thus spin currents are generated in all directions perpendicular to the current direction. At this time, a spin current generated in each direction has a spin component biased perpendicular to the direction. Based on the coordinate system depicted in FIG. 2, if an in-plane current in the conductive wire 204 flows in an x direction, among the generated spin current, a spin current flowing in a −z direction, namely a spin current incident to the free magnetic layer 203, has a y-directional or −y-directional spin component and flows to the free magnetic layer 203.

Due to the spin current flowing as above, the free magnetic layer 203 receives a great spin-torque, and the received spin-torque is called a spin-hall spin-torque. The magnetization of the free magnetic layer 203 receiving the spin-torque along with a magnetic field (not shown) applied from the outside experiences a flux reversal. Here, the external magnetic field may induce a flux reversal from a +z axis to a −z axis, or from a −z axis to a +z axis, depending on the direction of current applied by breaking the balance of the magnetization reaction with respect to the spin-hall spin-torque.

In addition, in the present disclosure, a voltage, namely an electric field, may be applied to a specific cell in order to induce a flux reversal selectively to a specific magnetic tunnel junction cell among a plurality of magnetic memory cells having a magnetic tunnel junction structure.

If a voltage, namely an electric field, is applied to the magnetic tunnel junction in a perpendicular direction, the perpendicular magnetic anisotropy energy density K⊥ of the magnetic layer varies. In other words, if a voltage is applied to the magnetic tunnel junction, an electric field is formed, and due to the formed electric field, a perpendicular magnetic anisotropy energy density of the magnetic body changes. For example, if the perpendicular magnetic anisotropy energy density reduced when applying a voltage V is defined as ΔK⊥(V), an effective anisotropic magnetic field H_{K,eff} perpendicular to the free magnetic layer is replaced with H_{K,eff}=2(K⊥−K⊥(V)/(M_{S}−N_{d}M_{S}). Therefore, when a voltage is applied, H_{K,eff} decreases. Since H_{K,eff} represents how strong the free magnetic layer is magnetized in a perpendicular direction, by applying a voltage to decrease H_{K,eff}, the magnetization of the free magnetic layer may be more easily reversed.

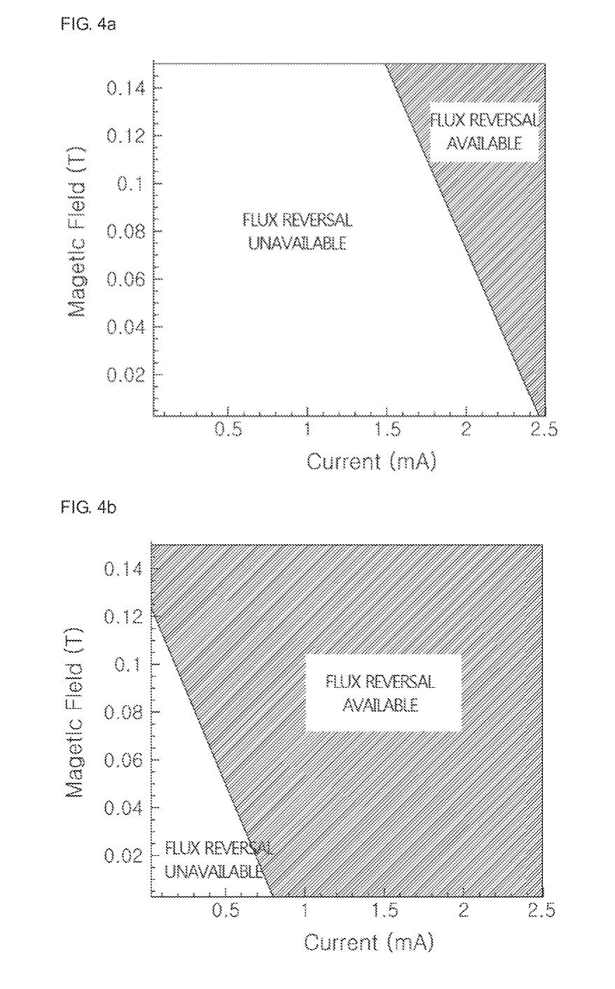

The principle of cell selection will be described in more detail with reference to FIG. 3. FIG. 3 is a cross-sectional view showing a configuration of a magnetic memory device according to an embodiment of the present disclosure in which a plurality of magnetic memory cells having a magnetic tunnel junction structure are joined to a conductive wire. In FIG. 3, a magnetic memory device is configured so that several magnetic tunnel junction structures 301 capable of selectively inducing a flux reversal by means of a spin-hall spin-torque, a magnetic field and an electric field are joined to the conductive wire 204.

By means of an element connected to the conductive wire 204 to apply a current thereto, a current flows into the plane of the conductive wire to cause a spin-hall spin-torque to all cells joined to the conductive wire 204, and by means of an element connected to each cell to apply a voltage thereto, a voltage is applied only to a specific cell to form an electric field and allows the specific cell to selectively induce a flux reversal.

In FIG. 3, when a plurality of magnetic memory cells 301 having a magnetic tunnel junction structure are joined to the conductive wire 204, if a current is applied through the conductive wire 204 and an external magnetic field (not shown) is applied thereto, the free magnetic layer of each cell may induce a flux reversal according to the above principle. The current flowing in the conductive wire 204 is provided from an element which is connected to an end of the conductive wire 204 to apply a current thereto. The current applying element may be a transistor or a diode.

At this time, if the applied current and magnetic fields have so great intensity to overcome perpendicular magnetic anisotropy of the free magnetic layer, the free magnetic layers of all cells connected to the conductive wire will induce a flux reversal. However, if a voltage is independently applied only to a cell which is to be selected in a state where a current and magnetic field with an insufficient intensity is applied, perpendicular magnetic anisotropy of the free magnetic layer included in the selected cell may decrease and thus only the cell may induce a flux reversal. The voltage applied to each cell is provided from an element which is independently connected to each cell to apply a voltage thereto. The voltage applying element may be a transistor or a diode.

At this time, a current is also applied to an unselected cell through the conductive wire 204, similar to the selected cell, but its intensity is not so great to overcome the perpendicular magnetic anisotropy, and thus a flux reversal is not induced.

As described above, there is a difference in magnetic anisotropy between a cell selected by applying a voltage and a cell unselected. If the magnetic anisotropy of a cell to which a voltage is applied to form an electric field decreases in comparison to a cell where an electric field is not formed, a flux reversal may be induced just with a smaller spin-hall spin-torque and magnetic field. In other words, if a voltage is applied only to a cell to be selected in a state where a suitable current is applied to the conductive wire 204 and an external magnetic field is applied thereto, a flux reversal may be induced only to the selected cell. In this case, since a current which generates a spin-hall spin-torque flows in the horizontal direction only at the conductive wire 204, this may be independent from thermal stability and tunnel magnetic resistance of the device, and thus it is possible to implement a magnetic memory device which simultaneously ensure thermal stability and increase tunnel magnetic resistance.

The magnetic memory device according to the present disclosure may be implemented as small as possible by using a patterning technique in order to obtain a high current density.

### MODE FOR INVENTION

Hereinafter, the present disclosure will be described in more detail based on examples. However, these examples are just for better understanding of the present disclosure, and it is obvious to those skilled in the art that the present disclosure is not limited or restricted by experiment conditions, materials or the like of the examples.

### EXAMPLE

Effects of the magnetic memory device according to the present disclosure have been checked by means of micro-magnetic modeling using a motion equation of magnetization.

The motion equation of magnetization may be expressed like Equation 3 below.

$$\frac{\partial m}{\partial t} = - γ m \times {H}_{eff} + α m \times \frac{\partial m}{\partial t} - \frac{{θ}_{SH} γ ℏ J}{2 {eM}_{S} d} m \times ( m \times \hat{y} ) \qquad Equation 3$$

In Equation 3, m represents a unit magnetization vector of the free magnetic layer 203, γ represents a magnetic rotation constant, H_{eff} represents all effective magnetic field vectors of the free magnetic layer 203, α represents a Gilbert damping constant, θ_{SH} represents a ratio of a spin current with respect to the applied current formed by the spin-hall effect, h (=1.05×10⁻³⁴ J·s) represents a value obtained by dividing a Planck constant by 2π, J represents an applied current density, e (=1.6×10⁻¹⁹C) represents an electron charge amount, M_{S} represents a saturation magnetization amount of the free magnetic layer, and d represents a thickness of the free magnetic layer 205. Coordinate directions (x, y, z) of Equation 3 are depicted in FIG. 2.

### Experimental Example 1

### Presence or Absence of a Flux Reversal of the Free Magnetic Layer According to a Current and a Magnetic Field Applied to the Device of the Present Disclosure

(1) As shown in FIG. 3, if each cell of the magnetic memory device according to an embodiment of the present disclosure is selected using a voltage or not selected, the presence or absence of a flux reversal of the free magnetic layer is determined depending on various in-plane currents applied to the conductive wire 204 and a magnetic field applied from the outside.

(2) Structure and properties of the device are as follows.

Cross-sectional area of the entire structure=400 nm′

Free magnetic layer 203: thickness (t)=2 nm, perpendicular magnetic anisotropy constant (K⊥)=8×10⁶ erg/cm³, saturation magnetization (M_{S})=1000 emu/cm³, Gilbert damping constant (α)=0.1, spin-hall angle (θ_{SH})=0.3′

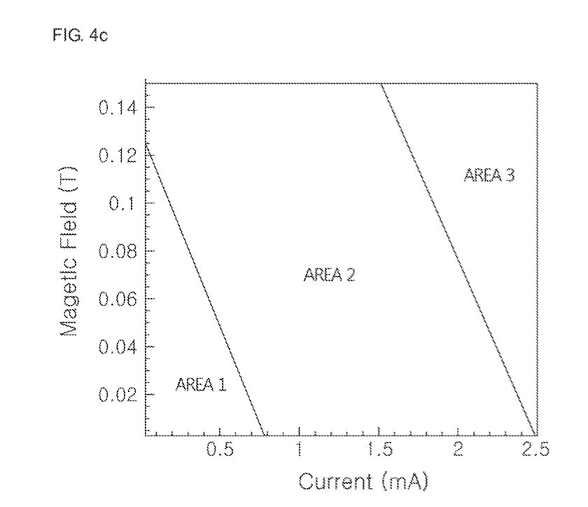

(3) FIG. 4a is a graph showing a presence or absence of a flux reversal of a free magnetic layer according to a current and a magnetic field applied to a cell when a voltage is not applied to the cell so that magnetic anisotropy of the free magnetic layer is not changed. In a ‘flux reversal unavailable’ area with a white background, a flux reversal of the free magnetic layer is not induced, and in a ‘flux reversal available’ area with a black background, a flux reversal is induced.

FIG. 4b is a graph showing a presence or absence of a flux reversal according to a current and a magnetic field applied to a selected cell when a voltage is applied to the cell so that perpendicular magnetic anisotropy of the free magnetic layer is reduced by 30%. In a ‘flux reversal unavailable’ area with a white background, a flux reversal of the free magnetic layer is not induced, and in a ‘flux reversal available’ area with a black background, a flux reversal is induced.

Referring to FIG. 4b, it can be found that a cell selected by applying a voltage thereto may induce a flux reversal of the free magnetic layer in a lower current and magnetic field area in comparison to the unselected cell of FIG. 4a.

FIG. 4c is a graph showing a presence or absence of a flux reversal according to a current and magnetic field in case of an unselected cell, to which a voltage is not applied, and a selected cell.

Referring to FIG. 4c, a flux reversal is not induced in both a selected cell and an unselected cell in Area 1, a flux reversal is induced only in a selected cell in Area 2, and a flux reversal is induced in both a selected cell and an unselected cell in Area 3. Therefore, if a current and a magnetic field corresponding to Area 2 are applied, it is possible to selectively induce a flux reversal only to a cell selected by applying a voltage.

Hereinafter, reference symbols used in the accompanying drawings will be explained briefly.
100: configuration of an existing magnetic memory device
101: fixed magnetic layer
102: insulating layer
103: free magnetic layer
200: configuration of a magnetic memory device according to the present disclosure
201: fixed magnetic layer
202: insulating layer
203: free magnetic layer
204: conductive wire
300: configuration of a magnetic memory device according to the present disclosure in which a plurality of magnetic memory cells with a magnetic tunnel junction structure are joined to a conductive wire
301: a plurality of magnetic memory cells with a magnetic tunnel junction structure adjacent to the conductive wire

### INDUSTRIAL APPLICABILITY

The magnetic memory device according to the present disclosure may implement high density integration by reducing a volume since a spin-hall spin-torque causing a flux reversal is generated at an interface of the conductive wire and the free magnetic layer, ensure thermal stability by enhancing perpendicular magnetic anisotropy of the magnetic layer, and reduce a critical current density by increasing an amount of spin current. In addition, by increasing tunnel magnetic resistance with a thick insulating body, the magnetic memory device according to the present disclosure may increase a reading rate without badly affecting the critical current density.

1. A magnetic memory device, comprising:
a plurality of magnetic memory cells, each including a fixed magnetic layer, an insulating layer and a free magnetic layer;
wherein the magnetic memory device comprises a conductive wire provided adjacent to the free magnetic layer to apply an in-plane current to the magnetic memory cell; a magnetic field provided to the magnetic memory cells; and an element configured to independently supplying a voltage to each of the magnetic memory cells,
wherein the fixed magnetic layer is a film having a fixed magnetization orientation and made of material magnetized in a direction perpendicular to a film surface,
wherein the free magnetic layer is a film having a variable magnetization orientation and made of material magnetized in a direction perpendicular to a film surface, and
wherein a magnetization orientation of each magnetic memory cell is selectively varied according to the applied in-plane current, the magnetic field provided to the magnetic memory cells, and the voltage supplied to each of the magnetic memory cells.

2. The magnetic memory device according to claim 1,
wherein the fixed magnetic layer is made of material selected from the group consisting of Fe, Co, Ni, B, Si, Zr, Pt, Tb, Pd, Cu, W, Ta and mixtures thereof.

3. The magnetic memory device according to claim 2,
wherein the fixed magnetic layer has a multi-layered film structure of a multi-layered film ((X/Y)ₙ, n≧1) formed by laminating an n number of double layers, each having an X-layer and a Y-layer, and
wherein the X-layer and the Y-layer are independently made of material selected from the group consisting of Fe, Co, Ni, B, Si, Zr, Pt, Tb, Pd, Cu, W, Ta and mixtures thereof.

4. The magnetic memory device according to claim 1,
wherein the fixed magnetic layer has a diamagnetic body structure including a first magnetic layer, a non-magnetic layer and a second magnetic layer,
wherein the first magnetic layer and the second magnetic layer are independently made of material selected from the group consisting of Fe, Co, Ni, B, Si, Zr, Pt, Tb, Pd, Cu, W, Ta and mixtures thereof, and
wherein the non-magnetic layer is made of material selected from the group consisting of Ru, Cu and mixtures thereof.

5. The magnetic memory device according to claim 4,
wherein at least one of the first magnetic layer and the second magnetic layer has a multi-layered film structure of a multi-layered film ((X/Y)ₙ, n≧1) formed by laminating an n number of double layers, each having an X-layer and a Y-layer, and
wherein the X-layer and the Y-layer are independently made of material selected from the group consisting of Fe, Co, Ni, B, Si, Zr, Pt, Tb, Pd, Cu, W, Ta and mixtures thereof.

6. The magnetic memory device according to claim 1,
wherein the fixed magnetic layer has an exchange-biased diamagnetic body structure including an anti-ferromagnetic layer; a first magnetic layer; a non-magnetic layer; and a second magnetic layer,
wherein the anti-ferromagnetic layer is made of material selected from the group consisting of Ir, Pt, Mn and mixtures thereof,
wherein the first magnetic layer and the second magnetic layer are independently made of material selected from the group consisting of Fe, Co, Ni, B, Si, Zr, Pt, Tb, Pd, Cu, W, Ta and mixtures thereof, and
wherein the non-magnetic layer is made of material selected from the group consisting of Ru, Cu and mixtures thereof.

7. The magnetic memory device according to claim 6,
wherein at least one of the first magnetic layer and the second magnetic layer has a multi-layered film structure of a multi-layered film ((X/Y)ₙ, n≧1) formed by laminating an n number of double layers, each having an X-layer and a Y-layer, and
wherein the X-layer and the Y-layer are independently made of material selected from the group consisting of Fe, Co, Ni, B, Si, Zr, Pt, Tb, Pd, Cu, W, Ta and mixtures thereof.

8. The magnetic memory device according to claim 1,
wherein the free magnetic layer is made of material selected from the group consisting of Fe, Co, Ni, B, Si, Zr, Pt, Tb, Pd, Cu, W, Ta and mixtures thereof.

9. The magnetic memory device according to claim 8,
wherein the free magnetic layer has a multi-layered film structure of a multi-layered film ((X/Y)ₙ, n≧1) formed by laminating an n number of double layers, each having an X-layer and a Y-layer, and
wherein the X-layer and the Y-layer are independently made of material selected from the group consisting of Fe, Co, Ni, B, Si, Zr, Pt, Tb, Pd, Cu, W, Ta and mixtures thereof.

10. The magnetic memory device according to claim 1,
wherein the insulating layer is made of material selected from the group consisting of AlOₓ, MgO, TaOₓ, ZrOₓ and mixtures thereof.

11. The magnetic memory device according to claim 1,
wherein the conductive wire configured to applying the in-plane current is made of material selected from the group consisting of Cu, Ta, Pt, W, Gd, Bi, Ir and mixtures thereof.

12. The magnetic memory device according to claim 1, further comprising:
a conductive wire adjacent to an outer side of the magnetic memory cell,
wherein an Oersted magnetic field formed when a current is applied to the conductive wire is used as a magnetic field provided to the magnetic memory cell.

13. The magnetic memory device according to claim 1,
wherein the magnetic memory cell further includes a magnetic layer having horizontal magnetic anisotropy at an outside of a laminated structure of the fixed magnetic layer, the insulating layer and the free magnetic layer, and
wherein a leaked magnetic field generated from the magnetic layer having horizontal magnetic anisotropy is used as a magnetic field provided to the magnetic memory cell.

14. The magnetic memory device according to claim 13,
wherein the magnetic layer having horizontal magnetic anisotropy is made of material selected from the group consisting of Fe, Co, Ni B, Si Zr and mixtures thereof.

15. The magnetic memory device according to claim 13, further comprising:
an anti-ferromagnetic layer adjacent to the magnetic layer having horizontal magnetic anisotropy,
wherein the magnetic layer having horizontal magnetic anisotropy has fixed magnetization due to the anti-ferromagnetic layer.

16. The magnetic memory device according to claim 15,
wherein the anti-ferromagnetic layer adjacent to the magnetic layer having horizontal magnetic anisotropy is made of material selected from the group consisting of IrMn, FeMn, PtMn and mixtures thereof.
